(19) United States
(12) Patent Application Publication
(10) Pub. No.: US 2013/0075747 A1
(43) Pub. Date: Mar. 28, 2013

(54) ESD PROTECTION USING LOW LEAKAGE ZENER DIODES FORMED WITH MICROWAVE RADIATION

(71) Applicant: Robert J. Purtell, West Jordan, UT (US)

(72) Inventor: Robert J. Purtell, West Jordan, UT (US)

(21) Appl. No.: 13/617,489

(22) Filed: Sep. 14, 2012

Related U.S. Application Data
(60) Provisional application No. 61/538,329, filed on Sep. 23, 2011.

(51) Int. Cl. H01L 29/866

(52) U.S. Cl. 257/75; 257/E29.335

(57) ABSTRACT

Semiconductor devices and methods for making such devices are described. These devices contain a semiconductor substrate with a first portion containing an integrated circuit device connected to a gate pad in an upper portion of the substrate and a second portion containing a Zener diode having a ESD rating up to about 10000 Volts, where the Zener diode is located around the periphery of the substrate. MW radiation can be used to form a single crystal Si material in a trench of the Zener diode 20, reducing the grain boundaries per unit area of the Zener diode by growing (or re-growing) the Si grains to a larger size while consuming the smaller grains. Thus, the leakage current from the Zener diode does not increase when the cross-sectional area of the Zener diode is increased from just surrounding the gate pad to encompass more of the substrate. Other embodiments are described.

### CROSS-REFERENCE TO RELATED APPLICATION

This application claims priority of U.S. Provisional Application Ser. No. 61/538,329 filed Sep. 23, 2011, the entire disclosure of which is incorporated herein by reference.

### FIELD

This application relates generally to semiconductor devices and methods for making such devices. More specifically, this application describes semiconductor devices containing integrated circuits protected from electrostatic discharge using low leakage, Zener diodes that have been formed with microwave radiation.

### BACKGROUND

Semiconductor devices containing integrated circuits (ICs) or discrete devices are used in a wide variety of electronic apparatus. The IC devices (or chips, or discrete devices) comprise a miniaturized electronic circuit that has been manufactured in the surface of a substrate of semiconductor material. The circuits are composed of many overlapping layers, including layers containing dopants that can be diffused into the substrate (called diffusion layers) or ions that are implanted (implant layers) into the substrate. Other layers are conductors (polysilicon or metal layers) or connections between the conducting layers (via or contact layers). IC devices or discrete devices can be fabricated in a layer-by-layer process that uses a combination of many steps, including growing layers, imaging, deposition, etching, doping and cleaning. Silicon wafers are typically used as the substrate and photolithography is used to mark different areas of the substrate to be doped or to deposit and define polysilicon, insulators, or metal layers.

IC devices can be susceptible to damaging electrostatic discharge (ESD) pulses from the operating environment and/or peripheral devices to which the IC device is exposed or connected. Zener diodes have often been used to protect the IC devices in these situations since they can shunt the voltage which may harm the device, as well as because of their low cost.

### SUMMARY

This application describes semiconductor devices and methods for making such devices. The semiconductor devices contain integrated circuit devices that can be partially or completely protected from electrostatic discharge using low leakage, Zener diodes that have been formed using microwave radiation. These semiconductor devices contain a semiconductor substrate, a first portion of the substrate containing an integrated circuit device connected to a gate pad in an upper portion of the substrate, and a second portion of the substrate containing a Zener diode having a ESD rating up to about 10000 Volts, wherein the Zener diode is located around the periphery of the substrate. Microwave radiation can be used to form a single crystal Si material in a trench of the Zener diode 20, thereby reducing the grain boundaries per unit area of the Zener diode by growing (or re-growing) the Si grains to a larger size while consuming the smaller grains. Thus, the leakage current from the Zener diode remains at an acceptable level even though the cross-sectional area of the Zener diode is increased from just surrounding the gate pad to encompass more of the substrate (i.e., including the source pad on the top of the substrate).

### BRIEF DESCRIPTION OF THE DRAWINGS

The following description can be better understood in light of the Figures, in which:

FIG. 1 shows some embodiments of a semiconductor structure containing a polysilicon layer;

FIG. 2 shows some embodiments of a semiconductor structure containing a patterned polysilicon layer;

FIG. 3 shows some embodiments of a semiconductor structure containing a mask on the patterned polysilicon layer;

FIG. 4 shows some embodiments of a semiconductor structure containing mesa structures;

FIG. 5 shows some embodiments of a semiconductor structure containing a mesa structure surrounding a trench;

FIG. 6 shows some embodiments of a semiconductor structure containing an upper Si layer being subjected to microwave radiation;

FIG. 7 shows some embodiments of a semiconductor structure containing a Zener diode; and

FIGS. 8 and 9 shows some embodiments of a semiconductor structure containing an IC device and a Zener diode.

The Figures illustrate specific aspects of the semiconductor devices and methods for making such devices. Together with the following description, the Figures demonstrate and explain the principles of the methods and structures produced through these methods. In the drawings, the thickness of layers and regions are exaggerated for clarity. The same reference numerals in different drawings represent the same element, and thus their descriptions will not be repeated. As the terms on, attached to, or coupled to are used herein, one object (e.g., a material, a layer, a substrate, etc.) can be on, attached to, or coupled to another object regardless of whether the one object is directly on, attached, or coupled to the other object or there are one or more intervening objects between the one object and the other object. Also, directions (e.g., above, below, top, bottom, side, up, down, under, over, upper, lower, horizontal, vertical, “x,” “y,” “z,” etc.), if provided, are relative and provided solely by way of example and for ease of illustration and discussion and not by way of limitation. In addition, where reference is made to a list of elements (e.g., elements a, b, c), such reference is intended to include any one of the listed elements by itself, any combination of less than all of the listed elements, and/or a combination of all of the listed elements.

### DETAILED DESCRIPTION

The following description supplies specific details in order to provide a thorough understanding. Nevertheless, the skilled artisan would understand that the semiconductor devices and associated methods of making and using the devices can be implemented and used without employing these specific details. Indeed, the semiconductor devices and associated methods can be placed into practice by modifying the illustrated devices and methods and can be used in conjunction with any other apparatus and techniques conventionally used in the industry. For example, while the description refers to semiconductor devices containing Zener diodes, it could be modified for any other types of semiconductor devices that require ESD protection and would benefit from reduced leakage. As well, while the description refers to U-MOS (U-shaped MOSFET) semiconductor devices, it could be modified for any other types of semiconductor devices which may or may not contain gate structures formed in a trench, such as LDMOS or CMOS devices, or even IC devices that are not formed in a trench.

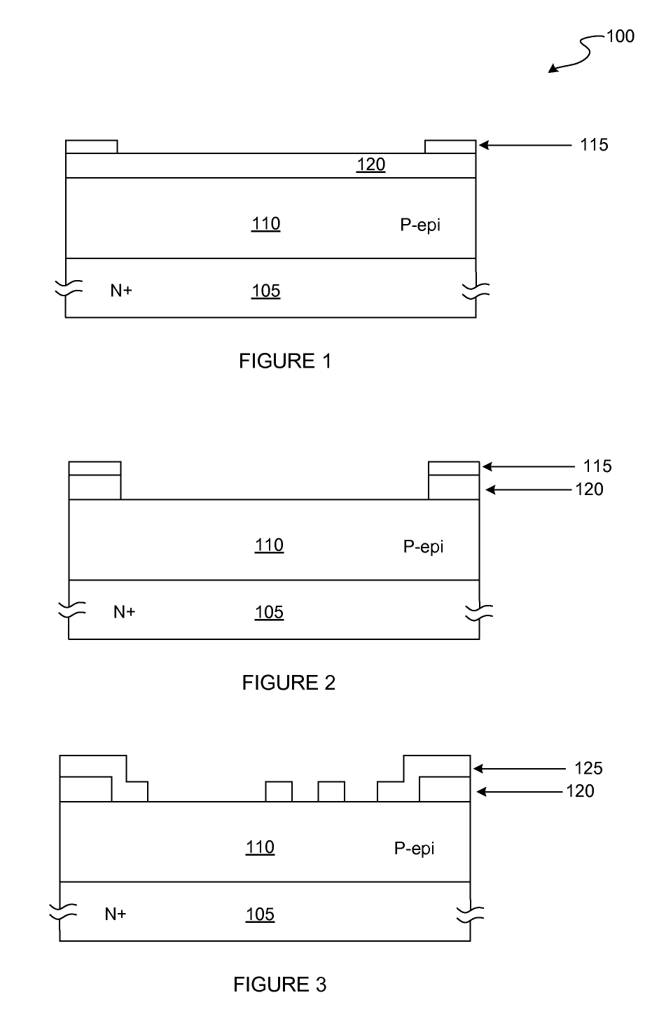

Some embodiments of the semiconductor devices and methods for making such devices are illustrated in the Figures and described herein. In these embodiments, the methods can begin as depicted in FIG. 1 when a semiconductor substrate 105 is first provided as part of the semiconductor structure 100. Any semiconductor substrate can be used as the substrate 105. Examples of some substrates include single-crystal silicon wafers, epitaxial Si layers, and/or bonded wafers such as used in silicon-on-insulator (SOI) technologies. Also, any other semiconducting material typically used for electronic devices can be used as the material for the substrate 105 under the right conditions, including Ge, SiGe, GaN, C, and/or any pure or compound semiconductors, such as III-V or II-VIs and their variants. Any or all of these substrates may remain undoped or be doped with any number of p-type or n-type dopant or combination of dopants. In some configurations, the substrate 105 comprises a single-crystal Si wafer which is heavily doped with any type or number of n-type dopants to the desired concentration, as shown in FIG. 1.

The semiconductor structure 100 can optionally contain one or more epitaxial (or “epi”) layers located on a portion of the upper surface of the substrate 105. In FIG. 1, the individual epitaxial layer (or multiple epitaxial layers) are depicted as epitaxial layer 110. In some configurations, the epitaxial layer 110 covers substantially the entire upper surface of substrate 105. Where Si is used as the material for the substrate 105, the epitaxial layer 110 comprises Si. The epitaxial layer(s) 110 can be provided using any process, including any epitaxial deposition process. In some instances, the epitaxial layer(s) can be lightly doped with any type or number of p-type dopants, as shown in FIG. 1.

In the embodiments shown in FIG. 1, a polysilicon layer 120 can then be deposited over the upper surface of the epi layer 110 using any process, such as chemical vapor deposition of silane, disilane, or tri-silane. The polysilicon layer 120 can remain undoped or can be doped with an implant, such as being in-situ doped with PH₃ while the polysilicon material is deposited. Next, as shown in FIG. 1, a mask 115 can be formed on the upper surface of the polysilicon layer 120 using any photolithography process that provides the mask 115 with the desired pattern. An etching process can then be used to remove the unprotected portions of the polysilicon layer 120 that are not covered with the mask 115, as shown in FIG. 2. This removal can be performed using any etching process, such as dry etch with SF₆ and chlorine. The mask 115 can then be removed using any process, such as etching in a peroxide/sulfuric acid mixture.

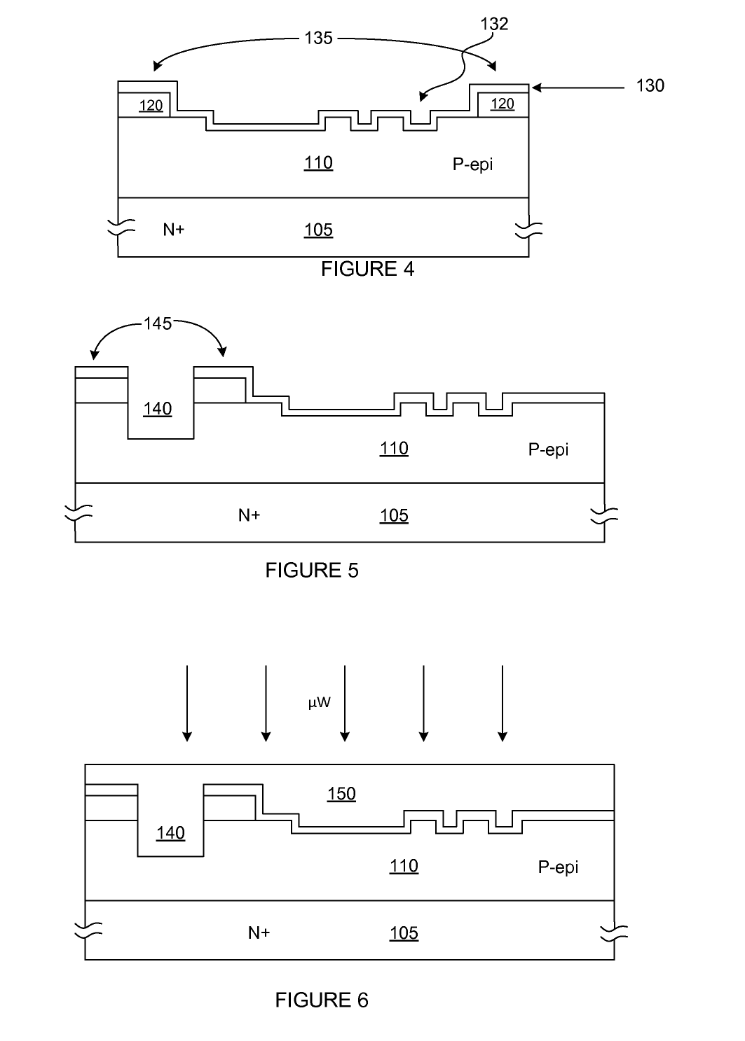

Next, as shown in FIG. 3, a second mask 125 can then be formed over the polysilicon layer 120 and part of the upper surface of the epi layer 110 using any photolithography process that provides the mask 125 with the desired pattern. The second mask 125 leaves portions of the epitaxial layer 110 exposed that will be removed later in the process (i.e., where part of a Zener diode will later be formed). An etching process can then be used to remove the unprotected portions of the epi layer 110 that are not covered with the second mask 125, as shown in FIG. 4. This removal can be performed using any etching process, such as one using etching in a peroxide/sulfuric acid mixture. The second mask 125 can then be removed using any process.

As shown in FIG. 4, an insulating layer 130 can be formed over the resulting structure. In some embodiments, the insulating layer 130 can be formed by depositing any known insulating material (i.e., silicon oxide) and/or by growing the insulating material until it covers the polysilicon layer 120 and the shallow trenches 132 that have been formed in the upper surface of the epitaxial layer 110. The insulating material can be deposited until the desired thickness is reached. The deposition of the insulating material can be carried out using any known high-quality deposition process, including any chemical vapor deposition (CVD) process (i.e., SACVD) which can produce a highly conformal step coverage within the shallow trenches 132. If needed, a reflow process can be used to reflow the deposited insulated material, thereby helping reduce voids or defects within the insulating material.

In some embodiments, the insulation layer 130 comprises an oxide layer. One example of an oxide layer is a shield oxide layer that can be formed by oxidizing the epitaxial layer 110 and the polysilicon layer 120 in an oxide-containing atmosphere until the desired thickness of the oxide has been grown. As shown in FIG. 4, the resulting semiconductor structure contains mesas 135 with an oxide layer 130 overlying the polysilicon layer 120.

Next, as shown in FIG. 5 (which focuses on a portion of the semiconductor structure 100 containing just a single mesa 135), a trench structure (or trench) 140 can be formed in the mesa structure 135. The result of this process is the formation of two mesa structures 145 surrounding the trench 140. The trench 140 can be formed by any process, including forming a third mask (not shown) on the upper surface of the mesa 135 and then etching the oxide layer 130, the polysilicon layer 120, and the material of the epitaxial layer 110 using that third mask using any etchant that will etch all of these materials. After the trench 140 has been created, the third mask can then be removed.

As shown in FIG. 6, a silicon layer 150 can then be deposited over the resulting structure. The Si layer 150 can be deposited with any non-single crystal structure. Thus, in some embodiments, the Si layer 150 can be deposited so that part or substantially the entire layer comprises an amorphous structure. In other embodiments, and under the right conditions, the Si layer 150 can be deposited so that part or substantially all of the layer comprises a polycrystalline structure.

The silicon layer 150 can optionally be doped with any dopant or combinations of dopants. For example, the silicon layer 150 can be doped with any number or type of P- and/or B-containing dopant materials since they can help or prevent void formation and movement of the silicon grains during thermal cycling. In some embodiments, the concentration of the P and/or B dopants in the Si layer 150 can range from about 1×10¹⁸ atoms/cm³ to about 3×10²⁰ atoms/cm³. In other embodiments, the concentration of the P and/or B dopant(s) in the Si layer 150 can range from about 1×10¹⁹ atoms/cm³ to about 2×10²⁰ atoms/cm³. In still other embodiments, the concentration can be any suitable combination or sub-range of these amounts.

The silicon layer 150 can be in situ doped and or implanted with these dopant(s) using any process. In some embodiments, the P and/or B dopant(s) can be added to the Si layer 150 using any process that will obtain the concentrations described herein. In other embodiments, such as where silane gas is used to form the Si layer 150, a P- and/or B-containing gas (or gases) can be added to the silane gas. The P- and/or B-containing gas(es) that can be used include diborane, PH₃, BCL₃, or combinations thereof. In yet other embodiments, the P and/or B dopant(s) can be implanted after the Si material (in the Si layer 150) has been formed.

The crystalline structure of the silicon layer 150 can then be modified to form a material with a single crystal structure. To modify the crystalline structure of the silicon layer 150, it can be heated with microwaves at a low temperature. It may optionally be heated by a supplemental heating system to reach the desired temperature for optimal grain growth (that can be induced by MW radiation). This process causes the Si crystal grains in the Si layer 150 to re-grow using the crystalline structure of the epitaxial layer 110 as a seed. The MW radiation can also activate the dopants in Si layer 150 if they are present. In some embodiments, these low temperatures can be less than about 800° C. In other embodiments, these low temperatures can range from about 200 to about 800° C. In yet other embodiments, the temperatures can range from about 200 to about 550° C. In still other embodiments, these low temperatures can be any suitable combination or sub-range of these temperatures.

The microwave heating process can use any frequency or wavelength of microwaves that are allowed for industrial applications by government regulations. In some embodiments, the frequency of the microwaves can range from about 2.45 GHz to about 5.8 GHz and have a wavelength ranging from about 52 mm to about 123 mm.

The microwave heating process can be performed for any time sufficient to re-crystallize the Si grains. In some embodiments, the time can range up to about 120 minutes, which is much shorter than the 5 to 6 hours that are often required in some conventional furnace processes used when forming epitaxial layers. In other embodiments, this time can range from about 1 minute to about 120 minutes. In yet other embodiments, the time can range from about 2 minutes to about 60 minutes. In still other embodiments, the time can range from about 2 minutes to about 15 minutes. In even other embodiments, the time can be any suitable combination or sub-range of these amounts.

In some embodiments, a combination of rapid thermal processing (RTP) and a MW anneal can be used to modify the crystalline structure. In these embodiments, the RTP can be performed from about 900 ° C. to about 1100 ° C. for about 2 to about 15 minutes and the MW anneal process can be performed from about 200 ° C. to about 550 ° C. for about 2 to about 30 minutes.

The result of this low temperature process using MW is the formation of a single crystal structure. In some configurations, the deposited Si layer 150 can comprise polycrystalline Si that can be converted to single-crystal Si structure by attaching the polysilicon material to a desired crystal face of the epitaxial layer 110 [i.e., (111), (100), or (110) or (311)]. When the deposited Si layer 150 is re-crystallized to a single-crystal structure 155, the underlying crystal plane (of the epitaxial layer 110) propagates through the material as it re-crystallizes.

In some configurations, the Si layer 150 could be deposited at same time microwave (MW) radiation is applied, thereby quickly growing large crystal Si structures. These configurations only involve a one step process not the two separate processes of deposition and re-crystallization. These configuration can therefore avoid the issue of volume reduction during re-crystallization of amorphous Si (a-Si).

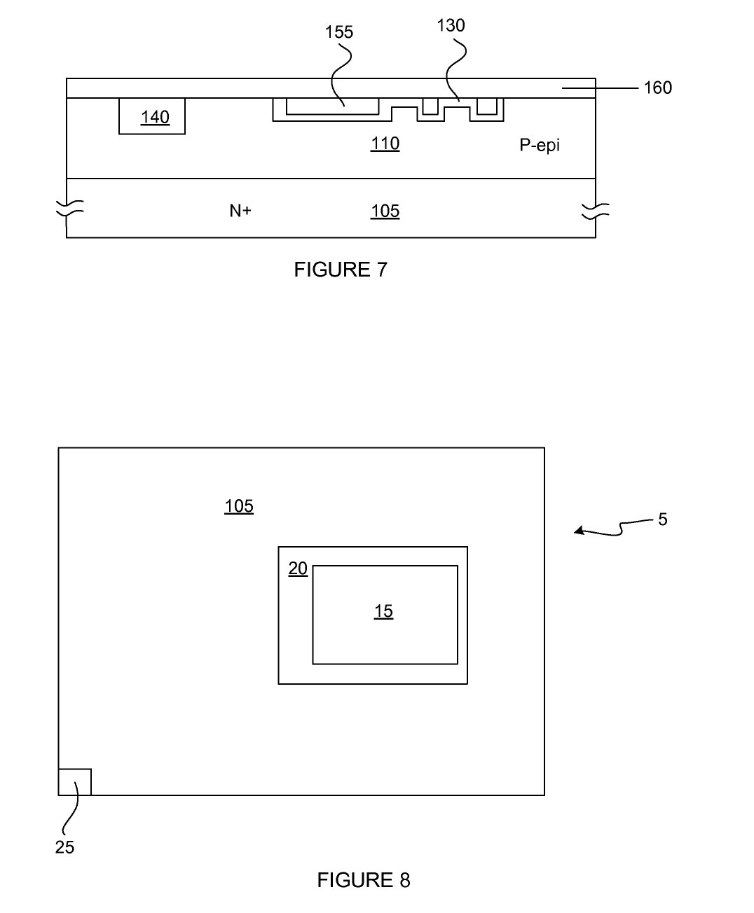

Next, as shown in FIG. 7, the semiconductor structure of FIG. 6 containing a single crystal layer 155 can be subjected to a planarization process. The planarization process (i.e., a CMP process) is performed until the upper surface of the epitaxial layer 110 is contacted. The result of the planarization process is removal of the mesa structures 145 and removal of the bulk of the single-crystal layer 155, thereby resulting in the structure shown in FIG. 7. Any barrier dielectric layer (such a low temperature oxide) can then be deposited over the planarized structure. An insulating layer 160 (such as BPSG) can then be formed over the upper surface of the resulting structure. Then, patterning, etching, liner, and fill processing can be performed to create contacts to the source and gate metals.

The single-crystal Si material in the trench 140 can be then be used to form a Zener diode using any processing that forms the structures described herein. In this processing, the single crystal material in the trench 140 has already been doped (whether by implanting or as an in-situ process) with an n-type dopant (P) or a p-type dopant (B). The material on either side of the trench 140 can then be doped with the opposite type of dopant using any process, such as by covering the trench 140 with a photoresist and then implanting the opposite type of dopant(s) to the desired concentration. This process forms a PN junction of the Zener diode with a single crystal Si structure in the trench 140 with its face containing the desired crystal orientation at a distance less than or equal to that which will allow propagation of the single crystal growth to propagate to the crystal structure in single crystal layer 155. The crystal orientations that could be used include those that would propagate with minimal distance to the orienting single crystal plane, minimal shrinkage and stress effects are also important considerations. These crystal orientations could be, for example, {100}, [110], or {311} orientations.

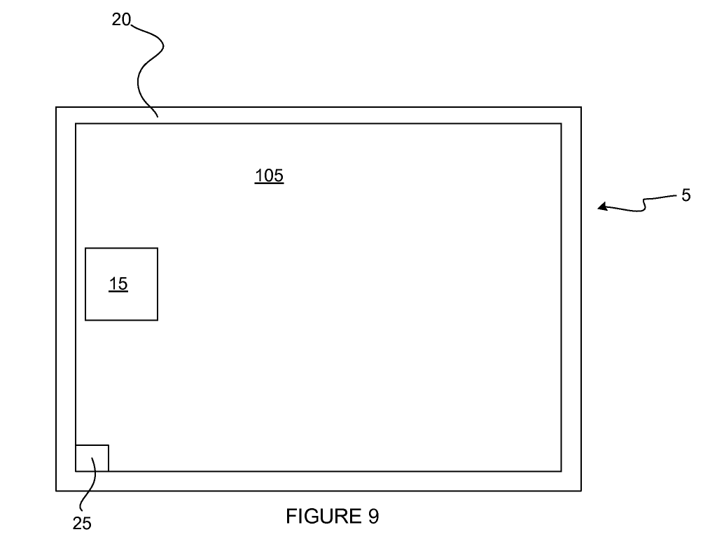

In some embodiments, this processing can be used to form the semiconductor structure depicted in FIG. 8 or 9 containing a Zener diode 20. The semiconductor device 5 contains a substrate 105 (optionally with an epitaxial layer 110 on its upper surface) with an IC device(s) connected to a gate pad 15 and a source pad 25 on the upper surface. The substrate 105 can contain any suitable number and/or type of integrated circuit (IC) devices. Examples of such IC devices can include, without limitation, transistors (e.g., bipolar junction transistors (BJT), metal-oxide-semiconductor-field-effect transistors (MOSFET), insulated-gate-field-effect transistors (IGFET), and/or any other suitable type of transistor. In some embodiments, the IC device comprises a transistor that has been formed in a trench structure, including UMOS (U-shaped MOSFET) devices, LDMOS (laterally-diffused MOSFET) devices, or combinations thereof. As known in the art, the IC device(s) contain a gate of the transistor that is connected to a gate pad 15 and a source that is connected to the source pad 25.

The semiconductor device 5 also contains a Zener diode 20, as shown in FIGS. 8 and 9. The Zener diode 20 can be formed as a ring around the gate pad 15 (as shown in FIG. 8) or around the periphery of the substrate 105 (as shown in FIG. 9). The Zener diode 20 contains a P/N junction that can operate in a reverse bias breakdown mode at specified currents without sustaining damage to the IC device in the substrate 105. The P/N junction can exhibit an avalanche breakdown at a specific range as the result of energizing thermally produced electron/hole pairs in the depletion region surrounding a P/N junction with the electric field associated with the reverse biased P/N junction. Given a sufficiently large electric field, energized electrons can eventually take on enough energy to ionize atoms of the semiconductor material in the depletion region. And the electrons that are released by ionization themselves become energized by the electric field, resulting in further ionization. The result of the chain reaction of ionization is the occurrence of sufficient numbers of charge carriers to enable the P/N junction to conduct electrical current.

In some configurations, the Zener diode 20 can be formed in part or all of the substrate 105 that does not contain the gate pad and source pad. For example, the Zener diode can be formed as a series of rings. Any number of rings can be formed, such as 2, 3, 4, or even more rings. The larger the area of the ring(s), the more current it can absorb during any electrostatic discharge (ESD) event. As well, the larger area of the ring(s), the higher the voltage it can discharge without damage to the gate oxide. In those embodiments where the Zener diode 20 is built or around the periphery of the substrate 105 instead of just the gate pad, a higher class rating can be achieved for a given number of rings if the leakage is not too severe, due to the larger grain sizes of the single crystal Zener diodes.

Some conventional Zener diodes used to protect a UMOS or LDMOS device are constructed around just the gate pad (similar to the configuration shown in FIG. 8). Such a configuration can provide an ESD rating ranging from 2000 to 4000 Volts for class 2 devices. But more complete protection of the entire device could be achieved if the Zener diode can be configured around the periphery of the substrate 105, as shown in FIG. 9, rather than just being located near the gate pad of the UMOS (or LDMOS) device. Forming conventional Zener diodes in such a configuration, however, would require increasing the cross-sectional area of the Zener diode and would raise the leakage current of the Zener diode to an unacceptable level. Thus, some conventional Zener diodes are not formed around the periphery of the substrate 105.

But the Zener diodes 20 described herein can be formed in all or part of the substrate 105 not containing the gate pad or source pad (including around the periphery of the substrate 105). As described herein, the MW radiation can be used to modify the crystalline structure and form the single crystal Si material in the trench 140 which is part of the Zener diode 20. The MW radiation is able to reduce the grain boundaries per unit area of the Zener diode by re-growing the grains to a larger size and thereby consuming the smaller grains. Thus, the leakage current from the Zener diode does not increase when the cross-sectional area of the Zener diode 20 is increased from just surrounding the gate pad 15 (as shown in FIG. 8) to around the periphery of the substrate 105 (as shown in FIG. 9). Such features thereby allow the ESD rating of the semiconductor devices in some embodiments to range up to about 10,000 Volts. In other embodiments, the ESD rating of the semiconductor devices can range from about 5000 Volts to about 10,000 V. In yet other embodiments, the ESD rating of class 2 devices could range from about 2000 to about 4000 V, the rating for class 3A devices could range from about 4000 to about 8000V, and the rating for class 3B device could be over 8000 V. And with reduced Zener leakage, a particular device could be raised to another class of device and/or the specific voltage rating within a class could be raised for a given Zener structure by using the MW radiation to form or re-crystallize the Si material.

In some instances, it can be easier to damage a small die since the input capacitance is lower and the voltage generated across the gate by an ESD event is higher. In other words, lower leakage Zener diodes can be produced by increasing the grain size or by producing single crystal grains, which can be useful for smaller die sizes.

It is understood that all material types provided herein are for illustrative purposes only. Accordingly, while specific dopants are names for the n-type and p-type dopants, any other known n-type and p-type dopants (or combination of such dopants) can be used in the semiconductor devices. As well, although the devices of the invention are described with reference to a particular type of conductivity (P or N), the devices can be configured with a combination of the same type of dopant or can be configured with the opposite type of conductivity (N or P, respectively) by appropriate modifications.

This application also relates to methods for making a semiconductor device comprising providing a semiconductor substrate, providing a first portion of the substrate with an integrated circuit device connected a gate pad and a source pad in an upper portion of the substrate, and providing a second portion of the substrate containing a Zener diode having a ESD rating up to about 10000 Volts, wherein the second portion comprises the periphery of the substrate.

In addition to any previously indicated modification, numerous other variations and alternative arrangements may be devised by those skilled in the art without departing from the spirit and scope of this description, and appended claims are intended to cover such modifications and arrangements. Thus, while the information has been described above with particularity and detail in connection with what is presently deemed to be the most practical and preferred aspects, it will be apparent to those of ordinary skill in the art that numerous modifications, including, but not limited to, form, function, manner of operation and use may be made without departing from the principles and concepts set forth herein. Also, as used herein, examples are meant to be illustrative only and should not be construed to be limiting in any manner.

1. A semiconductor device, comprising:
a semiconductor substrate;
a first portion of the substrate containing an integrated circuit device connected to a gate pad and a source pad in an upper portion of the substrate; and
a second portion of the substrate containing a Zener diode having a ESD rating up to about 10000 Volts, wherein the Zener diode is located around the periphery of the substrate.

2. The device of claim 1, wherein the ESD rating of the Zener diode ranges from about 5000 to about 10000 Volts.

3. The device of claim 1, wherein the ESD rating of the Zener diode ranges from about 2000 to about 4000 V for a class 2 semiconductor device, from about 4000 to about 8000V for a class 3A semiconductor device, and over about 8000 V for a class 3B semiconductor device.

4. The device of claim 1, wherein the integrated circuit device comprises a UMOS or LDMOS device.

5. The device of claim 1, wherein the second portion comprises substantially all of the substrate except for the first portion.

6. The device of claim 5, wherein the Zener diode is formed in substantially all of the second portion.

7. The device of claim 5, wherein the Zener diode is formed as a series of rings in the second portion of the substrate.

8. The device of claim 8, wherein the Zener diode comprise a single crystal Si material formed using microwave radiation.

9. The device of claim 8, wherein the Zener diode comprise a single crystal Si material that has been re-crystallized from amorphous Si using microwave radiation.

10. The device of claim 1, wherein the Zener diode comprise a single crystal Si material that has been re-crystallized from polysilicon using microwave radiation.

11. An electronic apparatus, comprising:
a printed circuit board; and
a semiconductor device comprising:
a semiconductor substrate;
a first portion of the substrate containing an integrated circuit device connected to a gate pad and a source pad in an upper portion of the substrate; and
a second portion of the substrate containing a Zener diode having a ESD rating up to about 10000 Volts, wherein the Zener diode is located around the periphery of the substrate.

12. The electronic apparatus of claim 11, wherein the ESD rating of the Zener diode ranges from about 5000 to about 10000 Volts.

13. The electronic apparatus of claim 11, wherein the ESD rating of the Zener diode ranges from about 2000 to about 4000 V for a class 2 semiconductor device, from about 4000 to about 8000V for a class 3A semiconductor device, and over about 8000 V for a class 3B semiconductor device.

14. The electronic apparatus of claim 11, wherein the integrated circuit device comprises a UMOS or LDMOS device.

15. The electronic apparatus of claim 11, wherein the second portion comprises substantially all of the substrate except for the first portion.

16. The electronic apparatus of claim 15, wherein the Zener diode is formed in substantially all of the second portion.

17. The electronic apparatus of claim 15, wherein the Zener diode is formed as a series of rings in the second portion of the substrate.

18. The electronic apparatus of claim 11, wherein the Zener diode comprise a single crystal Si material formed using microwave radiation.

19. The electronic apparatus of claim 18, wherein the Zener diode comprise a single crystal Si material that has been re-crystallized from amorphous Si using microwave radiation.

20. The electronic apparatus of claim 18, wherein the Zener diode comprise a single crystal Si material that has been re-crystallized from polysilicon using microwave radiation.
